(19) United States
(12) Patent Application Publication
(10) Pub. No.: US 2012/0169984 A1
(43) Pub. Date: Jul. 5, 2012

(54) DISPLAY SUBSTRATE AND METHOD OF MANUFACTURING THE SAME

(75) Inventors: Eun-Je JANG, Hwaseong-si (KR); Jeong-Uk Heo, Asan-si (KR); Hyun-Wuk Kim, Asan-si (KR); Joo-Hong Seo, Hwaseong-si (KR); Seon-Ah Cho, Busan (KR); You-Sik Shin, Asan-si (KR); Mi-Suk Kim, Cheonan-si (KR)

(73) Assignee: Samsung Electronics Co., Ltd., Suwon-si (KR)

(21) Appl. No.: 13/157,823

(22) Filed: Jun. 10, 2011

(30) Foreign Application Priority Data
Dec. 31, 2010 (KR) 10-2010-0139907

(51) Int. Cl. G02F 1/1343; H05K 3/10

(52) U.S. Cl. 349/139; 29/846

(57) ABSTRACT

A display substrate includes a gate line and a data line disposed on a base substrate. A switching element is connected to the gate line and the data line. A first pixel electrode is connected to the switching element, and a second pixel electrode is disposed on the first pixel electrode. The first pixel electrode includes first sub-electrodes that are separated by a first slit pattern. The second pixel electrode includes second sub-electrodes that are separated by a second slit pattern and extend across the first sub-electrodes. Therefore, a capacitance of a storage capacitor formed of overlapped portions of the first and second pixel electrodes is reduced, such that the charging rate of the storage capacitor is increased.

This application claims priority from and the benefit of Korean Patent Application No. 2010-0139907, filed on Dec. 31, 2010, which is hereby incorporated by reference for all purposes as if fully set forth herein.

### BACKGROUND OF THE INVENTION

1. Field of the Invention

Exemplary embodiments of the present invention relate to a display substrate and a method of manufacturing the display substrate.

2. Description of the Background

In general, a liquid crystal display (LCD) panel includes a display substrate, an upper substrate facing the display substrate, and a liquid crystal layer interposed between the display substrate and the upper substrate. The display substrate includes a plurality of signal lines and a plurality of thin-film transistors connected to the signal lines.

A conventional LCD panel employs a twisted nematic (TN) mode. However, a recently developed type of LCD panel employs a plane-to-line switching (PLS) mode, in order to provide an increased viewing angle.

A PLS mode LCD panel includes a common electrode overlapping with a pixel electrode, both of which are formed on a thin-film transistor substrate. A gray scale is embodied by liquid crystals that are vertically aligned by a fringe field formed between the pixel electrode and the common electrode.

A PLS mode LCD panel has a storage capacitor that is formed by overlapped portions of the common electrode and the pixel electrode. Such a storage capacitor is advantageous for providing a high aperture ratio. However, the charging rate of such a storage capacitor may be reduced in an LCD panel having a large size, a high resolution, and a high response speed, because the storage capacitor has a relatively large capacitance.

### SUMMARY OF THE INVENTION

Exemplary embodiments of the present invention provide a display substrate capable of improving a charging rate of a storage capacitor.

Exemplary embodiments of the present invention further provide a method of manufacturing the display substrate.

Additional features of the invention will be set forth in the description which follows, and in part will be apparent from the description, or may be learned by practice of the invention.

A display substrate, according to an exemplary embodiment of the present invention, includes a switching element, a first pixel electrode, and a second pixel electrode disposed on a base substrate. The switching element is connected to a gate line and a data line disposed on the base substrate. The first pixel electrode is disposed in a pixel area of the base substrate and is electrically connected to the switching element. The first pixel electrode includes a plurality of first sub-electrodes separated by a first slit pattern. The second pixel electrode includes a plurality of second sub-electrodes separated by a second slit pattern and crossing the first electrodes.

According to an exemplary embodiment of the present invention, a method for manufacturing a display substrate is provided. In the method, a switching element connected to a gate line and a data line is formed on a base substrate. A first pixel electrode is formed on a pixel area of the base substrate. The first pixel electrode is electrically connected to the switching element, and includes first sub-electrodes and a first peripheral electrode surrounding and connected to the first sub-electrodes. A second pixel electrode is formed on the first pixel electrode. The second pixel electrode includes second sub-electrodes that extend across the first sub-electrodes, and a second peripheral electrode surrounding and connected to the second sub-electrodes.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention, and together with the description serve to explain the principles of the invention.

FIG. 1 is a plan view illustrating a display panel, according to an exemplary embodiment of the present invention.

FIG. 2 is an enlarged view of the pixel illustrated in FIG. 1.

FIG. 3 is a cross-sectional view taken along line I-I′ of FIG. 1.

FIG. 4A is a plan view illustrating a method of forming a first conductive pattern of FIG. 3.

FIG. 4B is a cross-sectional view illustrating the method of forming the first conductive pattern of FIG. 3.

FIG. 5A is a plan view illustrating a method of forming a second conductive pattern of FIG. 3.

FIG. 5B is a cross-sectional view illustrating the method of forming the second conductive pattern of FIG. 3.

FIG. 6A is a plan view illustrating a method of forming a third conductive pattern of FIG. 3.

FIG. 6B is a cross-sectional view illustrating the method of forming the third conductive pattern of FIG. 3.

FIGS. 7A and 7B are cross-sectional views illustrating a method of forming a fourth conductive pattern of FIG. 3.

### DETAILED DESCRIPTION OF THE ILLUSTRATED EMBODIMENTS

The present invention is described more fully hereinafter with reference to the accompanying drawings, in which exemplary embodiments of the invention are shown. This invention may, however, be embodied in many different forms and should not be construed as limited to the exemplary embodiments set forth herein. Rather, these exemplary embodiments are provided so that this disclosure is thorough, and will fully convey the scope of the invention to those skilled in the art. In the drawings, the size and relative sizes of layers and regions may be exaggerated for clarity. Like reference numerals in the drawings denote like elements.

It will be understood that when an element or layer is referred to as being “on” or “connected to” another element or layer, it can be directly on or directly connected to the other element or layer, or intervening elements or layers may be present. In contrast, when an element is referred to as being “directly on” or “directly connected to” another element or layer, there are no intervening elements or layers present.

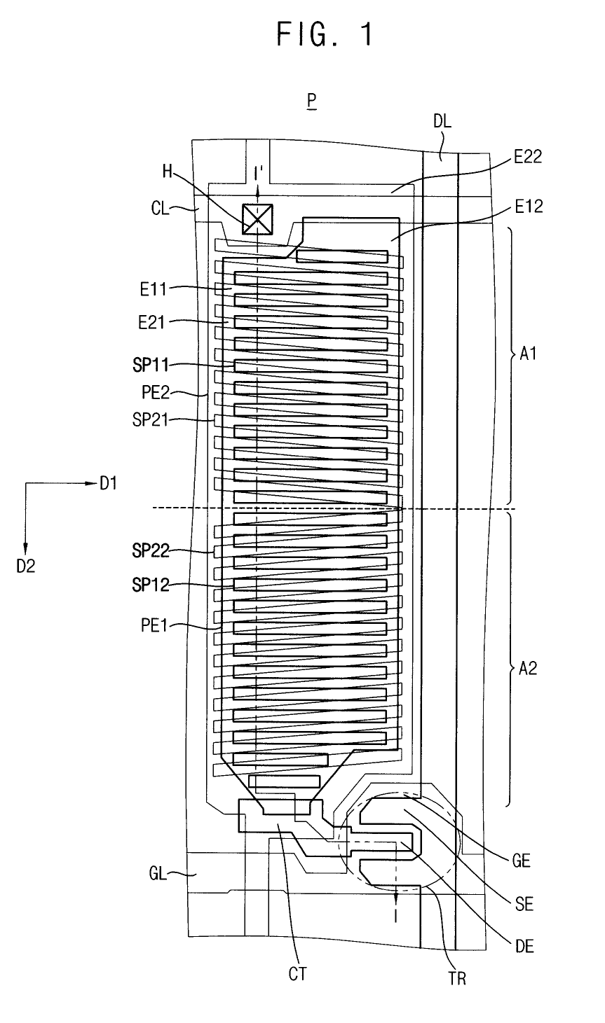

FIG. 1 is a plan view illustrating a display panel, according to an exemplary embodiment of the present invention. Referring to FIG. 1, the display panel includes a gate line GL, a data line DL, a common line CL, and a pixel P.

The gate line GL extends in a first direction D1, and a plurality of gate lines may be arranged in a second direction D2 crossing the first direction D1. The data line DL extends in the second direction D2, and a plurality of data lines may be arranged in the first direction D1. The common line CL extends in the first direction D1, and a plurality of common lines may be arranged in the second direction D2. The gate lines GL and the data lines DL may alternatively extend in the second direction D2 and the first direction D1, respectively.

The pixel P includes a switching element TR, a first pixel electrode PE1, and a second pixel electrode PE2. The switching element TR includes a gate electrode GE connected to the gate line GL, a source electrode SE connected to the date line DL, and a drain electrode DE spaced apart from the source electrode SE.

The first pixel electrode PE1 is electrically connected to the drain electrode DE. The first electrode includes a slit pattern. For example, the slit pattern includes a first slit pattern SP11 and a second slit pattern SP12. The first slit pattern SP11 includes openings that extend lengthwise at a first positive angle (+α°), with respect to the first direction D1. The second slit pattern SP12 includes openings that extend lengthwise, at a first negative angle (−α°), with respect to the first direction D1.

A pixel area, where the first pixel electrode PE1 is formed, may be divided into a first area A1 and a second area A2, by the first and second slit patterns SP11 and SP12. In particular, the first slit pattern SP11 may be formed on the first area A1, and the second slit pattern SP12 may be formed on the second area A2.

The first pixel electrode PE1 includes a plurality of bar-shaped first electrodes E11 (first sub-electrodes) that extend lengthwise at the first positive or negative angles (+α°, −α°). For example, the first electrodes E11 disposed in the first area A1 may be tilted with respect to the gate line, at an angle of about 0° to about 15°, with respect to the first direction D1. For example, the first electrodes E11 disposed in the second area A2 may be tilted with respect to the gate line GL, at an angle of about 0° to about −15°, with respect to the first direction D1. In other words, the first electrodes E11 may have a positive slope, with respect to the first direction, and the second electrodes E11 may have a negative slope, with respect to the first direction.

The first pixel electrode PE1 includes a first peripheral electrode E12 surrounding and connected to the first electrodes E11. The openings of first and second slit patterns SP11 and Sp12 are disposed between the first electrodes E11. Portions of the first peripheral electrode E12 may be parallel with the data line DL and portions may be parallel to the gate line GL. As illustrated in FIG. 1, the first peripheral electrode E12 may be spaced apart from the data line DL and the gate line GL, and may be partially overlapped with the common line CL.

The second pixel electrode PE2 is electrically connected to the common line CL, and overlapped with the first pixel electrode PE1. The second pixel electrode PE2 has a slit pattern that crosses the slit pattern of the first pixel electrode PE1. This slit pattern includes a third slit pattern SP21 and a fourth slit pattern SP22. The third slit pattern SP21 includes openings that extend lengthwise at a second positive angle (+β°), with respect to the first direction D1. The fourth slit pattern SP22 includes openings that extend lengthwise at a second negative angle (−β), with respect to the first direction D1. The third slit pattern SP21 may be disposed in the first area A1, and the fourth slit pattern SP22 may be disposed in the second area A2.

The second pixel electrode PE2 includes a plurality of bar-shaped second electrodes E21 (second sub-electrodes) that extend lengthwise at the second positive or negative angles (+β°, −β°). For example, the second electrodes E21 disposed in the first area A1 extend in parallel with each other at an angle of about 0° to about 15°, with respect to the first direction D1. The second electrodes E21 disposed in the second area A2 may extend in parallel at an angle of about 0° to about −15°, with respect to the first direction D1.

The second pixel electrode PE2 includes a second peripheral electrode E22 surrounding and connected to the second electrodes E21. Portions of the second peripheral electrode E22 may be parallel with the data line DL and portions may be parallel to the gate line GL. As illustrated in FIG. 1, the second peripheral electrode E22 may be spaced apart from the data line DL and the gate line GL, and may be partially overlapped with the common line CL. Although not illustrated, the second peripheral electrode E22 may be partially overlapped with the data line DL and the gate line GL, according to some aspects.

The first and second peripheral electrodes E12 and E22 may have longer sides that are disposed parallel with the data line DL. The second peripheral electrode E22 may be partially overlapped with the first peripheral electrode E12.

Referring to FIG. 1, the first electrodes E11 are shown to be parallel with the gate line GL, and the second electrodes E21 are shown to be tilted with respect to the gate line GL (i.e., with respect to the first direction D1). Alternatively, the second electrodes E21 may be parallel with the gate line GL, and the first electrodes E11 may be tilted with respect to the gate line GL, so as to cross the second electrodes E21. For example, a crossing angle formed by the first and second electrodes E11 and E21 may be about 0° to about 30°. In particular , the crossing angle may be less than about 30° and more than about 0°.

An overlapped area of the first and second pixel electrodes PE1 and PE2 may be referred to as a storage capacitor CST. The first and second pixel electrodes PE1 and PE2 respectively include the first and second electrodes E11 and E21 disposed across each other. The first and second electrodes E11 and E21 may form an entirely overlapped area, a partially overlapped area, and a non-overlapped area. Thus, the storage capacitor CST may be formed where the first and second electrodes E11 and E21 are overlapped with each other.

When the first and second electrodes E11 and E21 are partially overlapped, a capacitance of the storage capacitor CST is reduced. Therefore, a charging rate of the storage capacitor CST, during one horizontal period, may be increased (i.e., the charging time is decreased). As the charging rate of the storage capacitor CST is increased, a large display panel having a high resolution and a high response speed may exhibit excellent display characteristics. In addition, small/medium size display having the storage capacitor CST may also have excellent display characteristics.

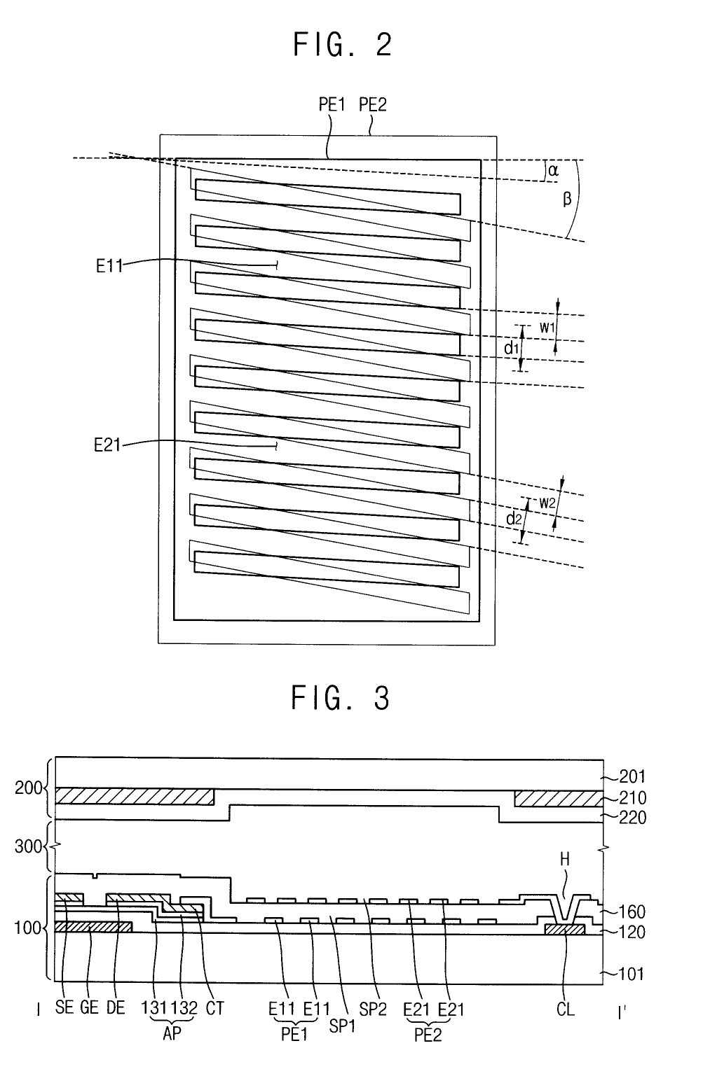

FIG. 2 is an enlarged view of the pixel illustrated in FIG. 1. Referring to FIGS. 1 and 2, the first pixel electrode PE1 has the first slit pattern SP 11. The first pixel electrode PE1 includes the first electrodes E11 separated by the openings of the first slit pattern SP11. The first electrodes E11 are angled at the first positive angle (+α°). The first electrodes E11 have a first width w1, and are spaced apart by a first pitch d1. The first width w1 may be about 2 μm to about 20 μm. The first pitch d1 may be about 5 μm to about 30 μm.

The second pixel electrode PE2 includes the second electrodes E21 that are separated by the openings of the third slit pattern SP21. The second electrodes E21are angled at the second positive angle (+β°). The second electrodes E21 have a second width w2, and are spaced apart by a second pitch d2. The second width w2 may be about 2 μm to about 20 μm. The second pitch d2 may be about 5 μm to about 30 μm. For example, a crossing angle formed by the first and second electrodes E11 and E21 may be about 0° to about 30°. In particular, the crossing angle may be less than about 30° and more than about 0°.

The following Table 1 represents simulation data including measured capacitance variations of a storage capacitor and transmittance variations, depending on a tilt angle of the second electrode E21, when the first electrode E11 is tilted by an angle of about 10°. The pitch of each of the first and second electrodes E11 and E21 is about 8 μm.

TABLE 1

| | | Transmittance | | Capacitance |
|---|---|---|---|---|
| Tilt angle | | variance when y | | variance when y |
| of second | Transmit- | axis is misaligned | Capaci- | axis is misaligned |
| electrode | tance | by +3 μM/−3 μM | tance | by +3 μM/−3 μm |
| −5° | 72.0% | 4.0% | 64.2% | 1.5% |
| 0° | 81.0% | 4.9% | 60.0% | 2.4% |
| 5° | 90.8% | 6.1% | 58.0% | 4.5% |
| 10° | 100.0% | 82.0% | 15.0% | 72.9% |
| 15° | 86.5% | 6.1% | 58.0% | 4.5% |

Referring to Table 1, when the tilt angle of the second electrode E21 is 10°, which is same as the tilt angle of the first electrodes E11, the transmittance is 100%, which is the highest charted value, in a structure having the first and second electrodes E11 and E21 alternately disposed in parallel with each other. However, the capacitance of a storage capacitor formed by such a structure is 15%, which is the smallest charted value. Furthermore, the transmittance variance and the capacitance variance, due to a misalignment of the first and second electrodes E11 and E21, are respectively 82.0% and 72.9%, which are relatively large values.

When the tilt angle of the second electrode E21 is 5°, a crossing angle of the first and second electrodes E11 and E21 is 5°, the transmittance is 90.8%, and the capacitance is 58.0%. The transmittance variance and the capacitance variance, due to a misalignment of the first and second electrodes E11 and E21, are respectively 6.1% and 4.5%.

When the tilt angle of the second electrode E21 is 0°, the crossing angle of the first and second electrodes E11 and E21 is 10°, the transmittance is 81.0%, and the capacitance is 60.0%. The transmittance variance and the capacitance variance, due to a misalignment of the first and second electrodes E11 and E21, are respectively 4.9% and 2.4%.

When the tilt angle of the second electrode E21 is −5°, the crossing angle of the first and second electrodes E11 and E21 is 15°, the transmittance is 72.0%, and the capacitance is 64.2%. The transmittance variance and the capacitance variance, due to a misalignment of the first and second electrodes E11 and E21, are respectively 4.2% and 1.5%.

According to the above, it can be noted that the transmittance variance and the capacitance variance, due to a misalignment of the first and second electrodes E11 and E21, are about 5% when the tilt angle of the second electrode E21 is from about 0° to about 5°, which means that the crossing angle of the first and second electrodes E11 and E21 is about 5° to about 10°.

FIG. 3 is a cross-sectional view of the display panel taken along line I-I′ of FIG. 1. Referring to FIGS. 1 and 3, the display panel includes a display substrate 100, an opposing substrate 200 facing the display substrate 100, and a liquid crystal layer 300 interposed between the display substrate 100 and the opposing substrate 200.

The display substrate 100 includes a first conductive pattern, a second conductive pattern, a third conductive pattern, and a fourth conductive pattern, which are formed on the first base substrate 101. The display substrate 100 may further include a first insulating layer 120 and a second insulating layer 160.

The first conductive pattern includes the gate line GL, the common line CL, and the gate electrode GE, of the switching element TR. The gate line GL extends in the first direction D1. The common line CL may be parallel with the gate line GL. The gate electrode GE extends from the gate line GL. The first conductive pattern may include a metal. The first insulating layer 120 is disposed on the first base substrate 101, so as to cover the first conductive pattern.

The second conductive pattern includes the data line DL, the source electrode SE, the drain electrode DE, and a contact portion CT. The data line DL extends in the second direction D2. The source electrode SE is connected to the data line DL, formed on the gate electrode GE, and may be U-shaped. The drain electrode DE is spaced apart from the source electrode SE and is formed on the gate electrode GE. The contact portion CT extends toward the first pixel electrode PE1 from the drain electrode DE and is electrically connected to the first pixel electrode PE1. The contact portion CT contacts the first pixel electrode PE1. Alternatively, when an insulating layer is formed to cover the first pixel electrode PE1, the contact portion CT may be electrically connected to the first pixel electrode PE1 through a contact hole formed in the insulating layer.

An active pattern AP may be disposed under the second conductive pattern. The active pattern AP includes a semiconductor layer 131 and an ohmic contact layer 132. The active pattern AP may be disposed directly under the second conductive pattern. The active pattern AP and the second conductive pattern may be patterned using the same mask.

The third conductive pattern includes the first pixel electrode PE1. The first pixel electrode PE1 contacts the contact portion CT, so that the first pixel electrode PE1 is electrically connected to the contact portion CT. The first pixel electrode PE1 includes the first electrodes E11, which are separated by the first and second slit patterns SP11 and SP12, and the first peripheral electrode E12. A portion of the first electrodes E11 disposed in the first area A1 are tilted at the first positive angle (+α°), and a portion of the first electrodes E11 disposed in the second area A2 are tiled at the first negative angle (−α°). The second insulating layer 160 is disposed on the first base substrate 101, so as to cover the third conductive pattern.

The fourth conductive pattern includes the second pixel electrode PE2. The second pixel electrode PE2 overlaps with the first pixel electrode PE1. The second pixel electrode PE2 contacts the common line CL through a contact hole H formed through the second insulating layer 160, so as to be electrically connected to the common line CL. The second pixel electrode PE2 includes the second electrodes E21 separated by the third and fourth slit patterns SP21 and SP22, and the second peripheral electrode E22. The second electrodes E21 disposed in the first area A1 are tilted at the second negative angle (+β°). The second electrodes E21 disposed in the second area A2 are tiled at the second negative angle (−β°).

As illustrated, the first and second electrodes E11 and E21 are alternately arranged, such that the first and second electrode E11 and E21 have an entirely overlapped area, a partially overlapped area, and a non-overlapped area. Thus, area of the storage capacitor CST formed by the first and second pixel electrodes PE1 and PE2 may be reduced. Therefore, a charging rate of the storage capacitor CST may be increased (i.e., the charging time is decreased). The increased charging rate of the storage capacitor CST provides a display panel having excellent display characteristics.

The opposing substrate 200 further includes a light blocking pattern 210 and a color filter 220, which are formed on a second base substrate 201. The light blocking pattern 210 overlaps with the data line DL and the gate line GL.

The color filter 220 overlaps with a pixel area of the first and second pixel electrodes PE1 and PE2. The color filter 220 may include a red color filter, a green color filter, and a blue color filter.

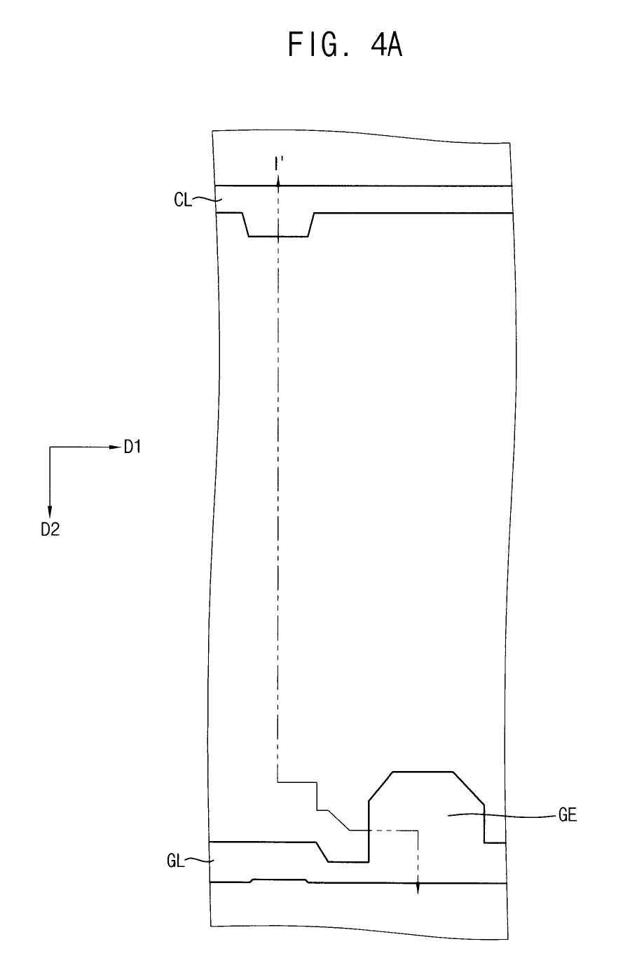

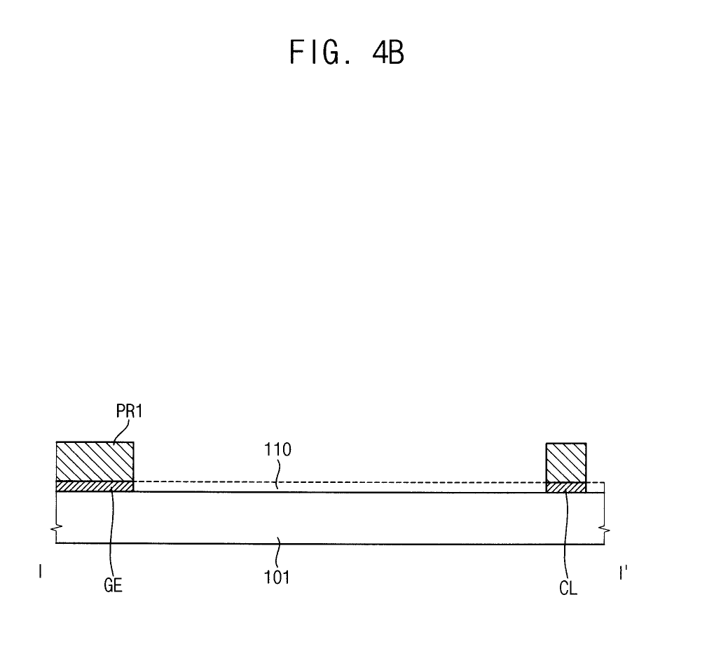

FIG. 4A is a plan view illustrating a method of forming the first conductive pattern of FIG. 3. FIG. 4B is a cross-sectional view illustrating the method of forming the first conductive pattern of FIG. 3. Referring to FIGS. 3, 4A, and 4B, a first metal layer 110 is formed on the first base substrate 101. Examples of a material that may be used for the first metal layer 110 include chromium, aluminum, tantalum, molybdenum, titanium, tungsten, copper, silver, an alloy thereof, and the like.

The first metal layer 110 may be deposited through a sputtering process. The first metal layer 110 may include at least two layers having different physical characteristics. The first metal layer 110 is patterned using a first photoresist pattern PR1, to form the first conductive pattern. The first conductive pattern includes the gate line GL, the common line CL, and the gate electrode GE of the switching element TR.

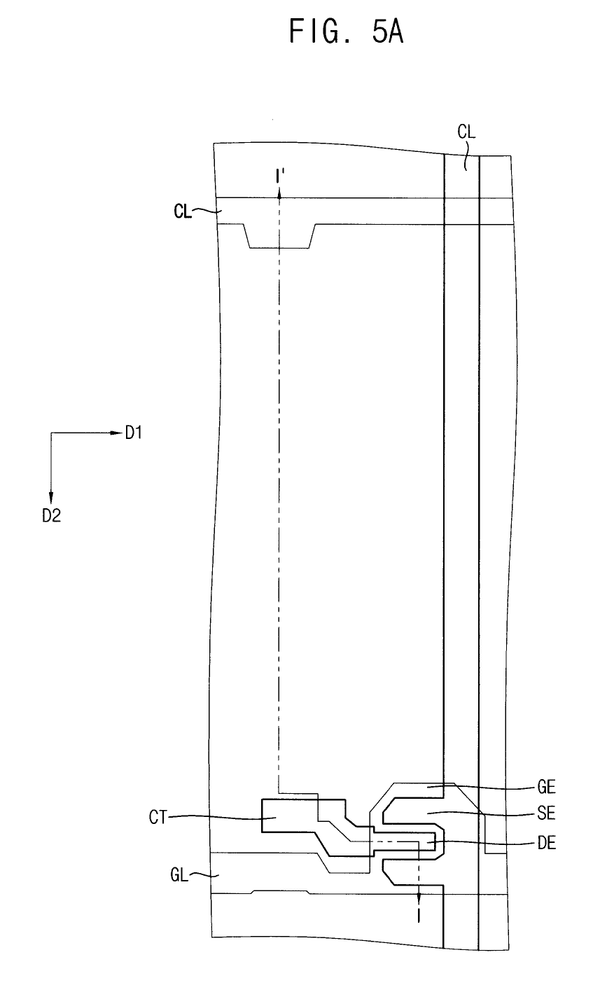

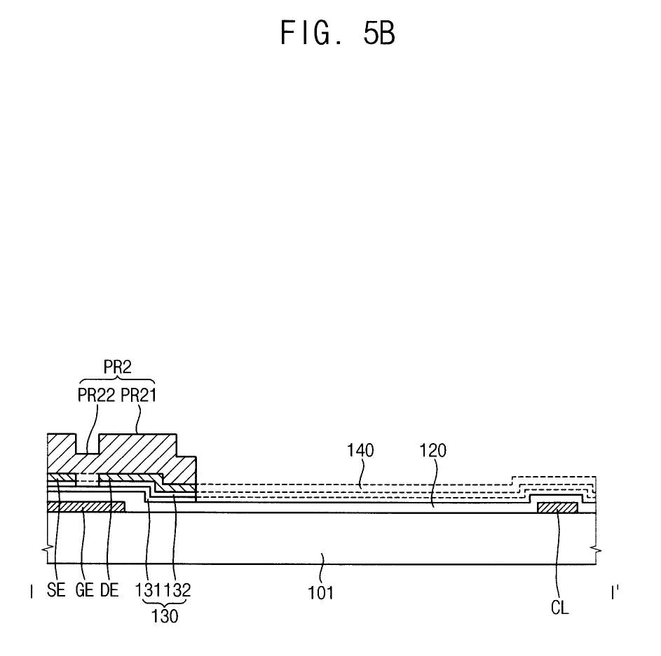

FIG. 5A is a plan view illustrating a method of forming the second conductive pattern of FIG. 3. FIG. 5B is a cross-sectional view illustrating the method of forming the second conductive pattern of FIG. 3. Referring to FIGS. 3, 5A, and 5B, the first insulating layer 120 is formed on the first base substrate 101 having the first conductive pattern. Examples of a material that may be used for the first insulating layer 120 include silicon nitride (SiNₓ) and silicon oxide (SiOₓ). The first insulating layer 120 may be formed through plasma enhanced chemical vapor deposition (PECVD). Furthermore, the first insulating layer 120 may have a double-layered structure, including two layers having different materials and/or formed through different methods.

An active layer 130 is formed on the first insulating layer 120. The active layer 130 includes a semiconductor layer 131 including amorphous silicon (a-Si:H), and an ohmic contact layer 132 including n+ amorphous silicon (n+ a-Si:H). The semiconductor layer 131 and the ohmic contact layer 132 may be formed through PECVD.

A second metal layer 140 is formed on the active layer 130. Examples of a material that may be used for the second metal layer 140 include chromium, aluminum, tantalum, molybdenum, titanium, tungsten, copper, silver, an alloy thereof, and the like. The second metal layer 140 may be deposited through a sputtering process. Furthermore, the second metal layer 140 may include at least two layers having different physical characteristics.

A second photoresist pattern PR2 is formed on the second metal layer 140. The second photoresist pattern PR2 is formed with a slit mask or a half-tone mask, so as to have a first photo pattern PR21 having a first thickness, and a second photo pattern PR22 having a smaller second thickness. The first photo pattern PR21 is disposed on the second conductive pattern including the data line DL, the source electrode SE, the drain electrode DE, and the contact portion CT. The second photo pattern PR22 is disposed between the source electrode SE and the drain electrode DE.

The second metal layer 140 and the active layer 130 are patterned using the second photoresist pattern PR2. Thereafter, an etch-back process is performed to remove the second photo pattern PR22 and reduce the thickness of the first photo pattern PR21. As a result, the first photo pattern PR21 remains above the second conductive pattern is formed. The second metal layer 140 is etched by using the remaining first photo pattern PR21, to form the source electrode SE and the drain electrode DE. A portion of the ohmic contact layer 132, which is exposed through a gap between the source and drain electrodes SE and DE, is removed to expose the semiconductor layer 131. As a result, a channel region of the switching element TR is formed.

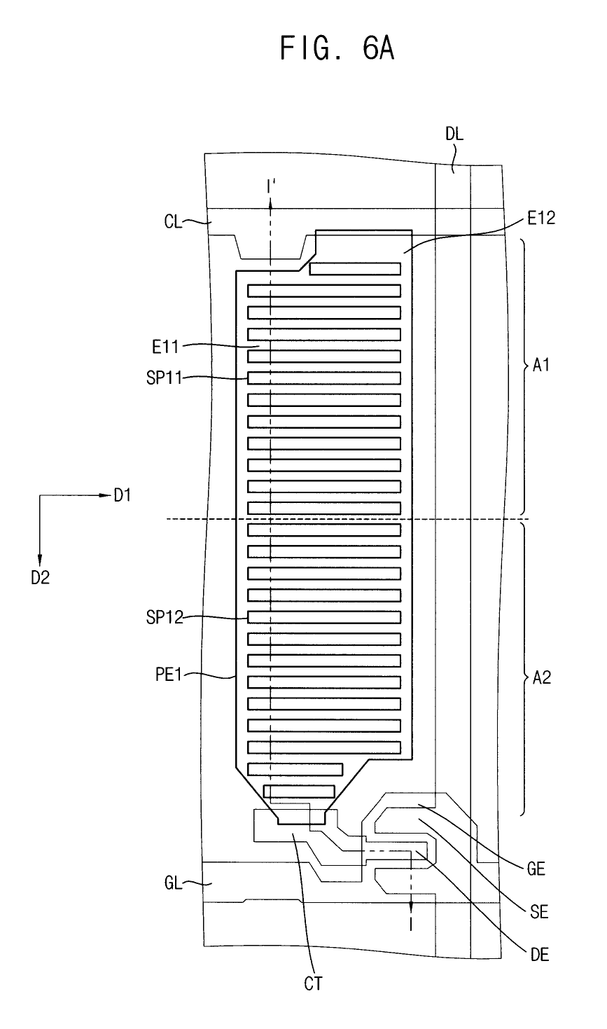

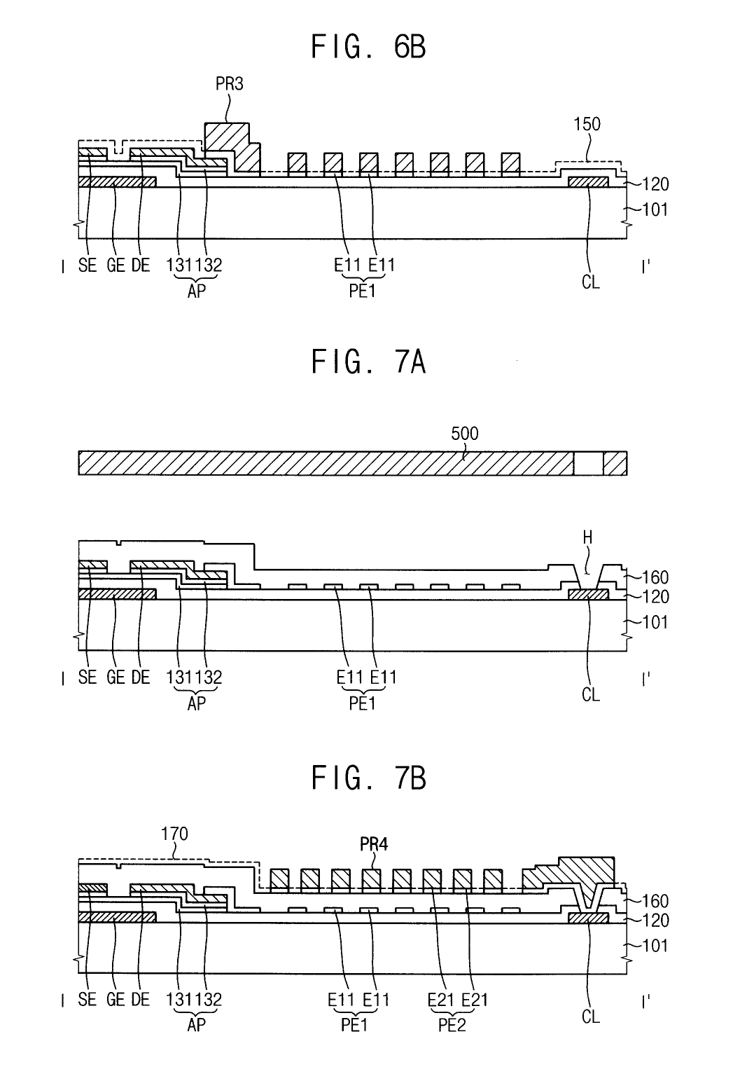

FIG. 6A is a plan view illustrating a method of forming the third conductive pattern of FIG. 3. FIG. 6B is a cross-sectional view illustrating the method of forming the third conductive pattern of FIG. 3. Referring to FIGS. 5A, 6A, and 6B, a first transparent conductive layer 150 is formed on the first insulating layer 120 and the second conductive pattern. Examples of a material that may be used for the first transparent conductive layer 150 include indium tin oxide (ITO), indium zinc oxide (IZO), and the like. The first transparent conductive layer 150 may be deposited through a sputtering process.

A third photoresist pattern PR3 is formed on the first transparent conductive layer 150. The first transparent conductive layer 150 is patterned using the third photoresist pattern PR3, to form the third conductive pattern. The third conductive pattern includes the first pixel electrode PE1. The first pixel electrode PE1 makes contact with the contact portion CT, and has the first and second slit patterns SP11 and SP12. Thus, the first pixel electrode PE1 includes the first electrodes E11 and the first peripheral electrode E12. The first electrodes E11 may be tilted at the first positive or negative angles (+α°, −α°).

In the present exemplary embodiment, the third photoresist pattern PR3 is formed on the first transparent conductive layer 150. However, the first transparent conductive layer may be formed after the third photoresist pattern is formed on the second conductive pattern. When the first transparent conductive layer is formed on the third photoresist pattern, the third photoresist pattern has an opening for the third conductive pattern, and the first transparent conductive layer is formed in the opening and on the third photoresist pattern. In a following stripping process, the first transparent conductive layer formed on the third photoresist pattern is removed, such that the third conductive pattern is formed.

FIGS. 7A and 7B are cross-sectional views illustrating a method of forming the fourth conductive pattern of FIG. 3. Referring to FIGS. 3, 7A, and 7B, the second insulating layer 160 is formed on the third conductive pattern. Examples of a material that may be used for the second insulating layer 160 include silicon nitride (SiNₓ) and silicon oxide (SiOₓ). The second insulating layer 160 may be formed through PECVD. The second insulating layer 160 may have a double-layered structure including two layers having different materials and/of formed through different methods. The second insulating layer 160 may include an organic material.

A portion of the second insulating layer 160 is removed using a mask 500, to form a contact hole H exposing the common line CL. A second transparent conductive layer 170 is formed on the second insulating layer 160 the contact hole H. Examples of a material that may be used for the second transparent conductive layer 170 include indium tin oxide (ITO), indium zinc oxide (IZO), and the like. The second transparent conductive layer 170 may be deposited through a sputtering process.

The second transparent conductive layer 170 is patterned by using a fourth photoresist pattern PR4 to form the fourth conductive pattern. The fourth conductive pattern includes the second pixel electrode PE2. The second pixel electrode PE2 makes contact with the common line CL through the contact hole H.

In the present exemplary embodiment, the fourth photoresist pattern PR4 is formed on the second transparent conductive layer 170. However, the fourth photoresist pattern may be formed on the second insulating layer 160, using a slit mask or a half-tone mask. The fourth photoresist pattern formed on the second insulating layer 160 includes a first photo pattern disposed in an area where the fourth conductive pattern is not formed, and a second photo pattern disposed in an area where the fourth conductive pattern is formed. The first photo pattern has a first thickness, and the second photo pattern has a smaller second thickness smaller. The fourth photoresist pattern has a hole exposing the second insulating layer 160.

An exposed portion of the second insulating layer 160 is removed to form the contact hole H. The second photo pattern is removed through an etch-back process, so that the first photo pattern remains on an area where the fourth conductive pattern is not formed. Therefore, an opening is formed to expose the second insulating layer 160, and the second transparent conductive layer is formed in the opening and on the first photo pattern. In a subsequent stripping process, a portion of the second conductive layer formed on the first photo pattern is removed, to form the fourth conductive pattern. When the fourth photoresist pattern is formed using a slit mask or a half-tone mask, the process for forming the contact hole H illustrated in FIG. 7A may be omitted.

As illustrated, the first and second electrodes E11 and E21 are alternately arranged, such that the first and second electrode E11 and E21 form an entirely overlapped area, a partially overlapped area, and a non-overlapped area. Thus, the storage capacitor CST formed by the first and second pixel electrodes PE1 and PE2 may be reduced. Therefore, a charging rate of the storage capacitor CST, during a horizontal period (1H), may be increased.

According to the exemplary embodiments of the present invention, the first pixel electrode includes bar-shaped first electrodes, and the second pixel electrode overlaps with the first pixel electrode and includes the bar-shaped second electrodes crossing the first electrodes. Therefore, a charging rate of the storage capacitor CST, during a horizontal period (1H), may be increased. Thus, a display panel having excellent display quality may be produced.

It will be apparent to those skilled in the art that various modifications and variation can be made in the present invention without departing from the spirit or scope of the invention. Thus, it is intended that the present invention cover the modifications and variations of this invention provided they come within the scope of the appended claims and their equivalents.

What is claimed is:

1. A display substrate comprising:
a base substrate comprising a pixel area;
a gate line disposed on the base substrate and extending in a first direction;
a data line disposed on the base substrate and extending across the gate line in a second direction;
a switching element disposed on the base substrate and connected to the gate line and the data line;
a first pixel electrode disposed in the pixel area and connected to the switching element, the first pixel electrode comprising first sub-electrodes spaced apart from each other by a slit pattern; and
a second pixel electrode comprising second sub-electrodes spaced apart from each other by a slit pattern, the second sub-electrodes extending across the first sub-electrodes.

2. The display substrate of claim 1, wherein:
the first pixel electrode further comprises a first peripheral electrode surrounding and connected to the first sub-electrodes; and
the second pixel electrode further comprises a second peripheral electrode surrounding and connected to the second sub-electrodes.

3. The display substrate of claim 1, wherein the first sub-electrodes extend parallel to each other at an angle of about 0° to about 15°, with respect to the first direction or the second direction.

4. The display substrate of claim 1, wherein the second sub-electrodes extend parallel to each other at angle of about 0° to about 15°, with respect to the first direction or the second direction.

5. The display substrate of claim 1, wherein a crossing angle of the first sub-electrodes and the second sub-electrodes is more than about 0° and less than about 30°.

6. The display substrate of claim 1, further comprising a common line disposed on the base substrate, extending in the first direction, and connected to the second pixel electrode.

7. The display substrate of claim 6, further comprising an insulating layer disposed between the first pixel electrode and the second pixel electrode and comprising a contact hole exposing the common line,
wherein the second pixel electrode is connected to the common line through the contact hole.

8. The display substrate of claim 7, wherein the first pixel electrode is connected to a contact portion extending from the switching element.

9. The display substrate of claim 1, wherein the width of each of the first sub-electrodes is about 2 μm to about 20 μm, and the width of each of the second sub-electrodes is from about 2 μm to about 20 μm.

10. The display substrate of claim 1, wherein the pitch of the first sub-electrodes is about 5 μm to about 30 μm, and the pitch of the second sub-electrodes is from about 5 μm to about 30 μm.

11. The display substrate of claim 1, wherein:
the pixel area is divided into a first portion and a second portion;
the first sub-electrodes are each disposed in one of the first portion and the second portion;
the first sub-electrodes disposed in the first portion have a positive slope, with respect to the first direction or the second direction; and
the first sub-electrodes disposed in the second portion have a negative slope, with respect to the first direction or the second direction.

12. The display substrate of claim 11, wherein:
the second sub-electrodes are each disposed in one of the first portion and the second portion;
the second sub-electrodes disposed in the first portion have a positive slope, with respect to the first direction or the second direction; and
the second sub-pixel electrodes disposed in the second portion have a negative slope, with respect to the first direction or the second direction.

13. A method for manufacturing a display substrate, the method comprising:
forming a gate line and a data line on a base substrate, the gate line extending in a first direction and the data line extending in a second direction across the gate line;
forming a switching element on the base substrate and connected to the gate line and the data line;
forming a first pixel electrode on a pixel area of the base substrate, the first pixel electrode being connected to the switching element and comprising first sub-electrodes and a first peripheral electrode surrounding and connected to the first sub-electrodes; and
forming a second pixel electrode comprising second sub-electrodes that extend across the first sub-electrodes, and a second peripheral electrode surrounding and connected to the second sub-electrodes.

14. The method of claim 13, wherein the forming of the switching element comprises:
forming a first metal layer on the base substrate;
forming a first conductive pattern by patterning the first metal layer, the first conductive pattern comprising the gate line, and a gate electrode connected to the gate line;
forming a second metal layer on the first conductive pattern; and
forming a second conductive pattern by patterning the second metal layer, the second conductive pattern comprising the data line, a source electrode connected to the data line, a drain electrode, and a contact portion extending from the drain electrode.

15. The method of claim 14, wherein the forming of the first pixel electrode comprises:
forming a first transparent conductive layer on the second conductive pattern; and
patterning the first transparent conductive layer to form the first pixel electrode.

16. The method of claim 14, further comprising forming an active layer on the base substrate before the forming of the second metal layer,
wherein an active pattern is formed under the second conductive pattern.

17. The method of claim 14, wherein the forming of the first conductive pattern comprises forming a common line on the base substrate that extends parallel with the gate line.

18. The method of claim 17, further comprising:
forming an insulating layer on the first pixel electrode; and
forming a contact hole in the insulating layer to expose the common line.

19. The method of claims 18, wherein the forming of the second pixel electrode comprises:
forming a second transparent conductive layer on the insulating layer and in the contact hole; and
patterning the second transparent conductive layer to form the second pixel electrode, the second pixel electrode being connected to the common line through the contact hole.

20. The method of claim 13, wherein a crossing angle of the first sub-electrodes and the second sub-electrodes is more than about 0° and less than about 30°.

21. The method of claim 13, wherein the first sub-electrodes extend in parallel to each other at an angle of about 0° to about 15°, with respect to the first direction or the second direction; and
the second sub-electrodes extend in parallel to each other at an angle of from about 0° to about 15°, with respect to the first direction or the second direction.
